(19) United States
(12) Patent Application Publication
(10) Pub. No.: US 2022/0025240 A1
(43) Pub. Date: Jan. 27, 2022

(54) METHOD OF MANUFACTURING SEMICONDUCTOR DEVICES USING A HEAT TRANSFER FLUID COMPRISING FLUORINATED COMPOUNDS HAVING A LOW GWP

(71) Applicant: SOLVAY SPECIALTY POLYMERS ITALY S.P.A., Bollate (IT)

(72) Inventors: Emanuela ANTENUCCI, Saronno (IT); Letanzio BRAGANTE, Due Carrare (IT); Valeriy KAPELYUSHKO, Alessandria (IT); Stefano MILLEFANTI, Tradate (IT)

(21) Appl. No.: 17/312,032

(22) PCT Filed: Dec. 19, 2019
(86) PCT No.: PCT/EP2019/086212

§ 371 Date: Jun. 9, 2021

(30) Foreign Application Priority Data
Dec. 20, 2018 (EP) 18214417.0

(51) Int. Cl. C09K 5/10; C09K 5/04; H01L 21/67

(52) U.S. Cl. CPC C09K 5/10; H01L 21/67109; C09K 5/048

(57) ABSTRACT

The present invention relates to a method for manufacturing semiconductor devices, including a step wherein a semi-conductor device exchanges heat with a heat transfer fluid. The heat transfer fluid comprises one or more chemical compounds having the general formula: Ph(OR_{f})ₓ (I) wherein Ph is an aromatic ring linked to one or more ether groups —OR_{f} where each —R_{f}: — is a monovalent fluorinated alkyl group comprising at least one C—F bond, — has a carbon chain, preferably a C₁-C₁₀ carbon chain, which can be linear or can comprise branches and/or cycles, and, optionally, can comprise in chain heteroatoms selected from O, N or S, and wherein, when X>1, the —R^{f} groups on the same molecule can be equal to or different from each other.

### TECHNICAL FIELD

This application claims priority to EP application 18214417.0 filed on 20 Dec. 2018, the whole content of this application being incorporated herein by reference for all purposes.

The present invention relates to a method for manufacturing semiconductor devices using heat transfer fluids comprising selected fluorinated compounds having low GWP.

### BACKGROUND ART

In the semiconductor industry temperature control is a highly important part of the manufacturing control systems. The manufacturing of semiconductor devices such as integrated circuits goes through different steps, such as the preparation of the silicone wafers, the creation of the device (e.g. an integrated circuit such as a processor) and the testing which is performed at several stations along the manufacturing process and is an integral part of the manufacturing as only the devices which are able to pass the required tests are then released for subsequent usage.

Heat transfer fluids are used to remove or add heat or to maintain a certain temperature in numerous processes which are regularly performed during the manufacturing of semiconductor devices.

Heat transfer fluids in general are used to transfer heat from one body to another, typically from a heat source to a heat sink so as to effect cooling of the heat source, heating of the heat sink or to remove unwanted heat generated by the heat source. The heat transfer fluid provides a thermal path between the heat source and the heat sink; it may be circulated through a loop system or other flow system to improve heat flow or it can be in direct contact with heat source and heat sink. Simpler systems use simply an airflow as heat transfer fluid, more complex system use specifically engineered gases or liquids which are heated or refrigerated in a portion of the system and then are delivered in thermal contact with the semiconductor device to exchange heat with it.

Temperature control units (TCUs) are used all along the production line for the fabrication of semiconductor devices, and use heat transfer fluids to remove unwanted heat during steps like wafer etching and deposition processes, ion implantation and lithographic processes. The heat transfer fluid is typically circulated through the wafer mounts and each process tool which require temperature control has its own individual TCU.

Some tools of particular importance as far as temperature control is concerned, are silicone wafer etchers, steppers and ashers. Etching is performed using reactive plasma at temperatures ranging from 70° C. to 150° C. and the temperature of the wafer must be controlled precisely during the plasma treatment. Following the plasma treatment the etched parts are normally immersed in a solvent which removes the etched parts. This second step does not normally require temperature control as it is performed at mild or ambient temperature. When referring to an “etcher” in the present application, it is intended the equipment wherein the plasma treatment at high temperature is performed and which therefore requires a TCU.

Steppers are used in the photolithography of wafers to form the reticules which are then used to expose the photosensitive mask. This process is carried out at temperatures between 40° C. and 80° C., however temperature control is extremely important as the wafer need to be maintained at a precise fixed temperature (+/−0.2° C.) along the process to ensure good results.

Ashing is a process where the photosensitive mask is removed from the wafer and which is performed at temperatures from 40° C. to 150° C. The system uses plasma and also here temperature control is particularly important.

Another relevant process is plasma enhanced chemical vapour deposition (PECVD) wherein films of silicon oxide, silicon carbide and/or silicone nitride are grown on a wafer within a chamber. Also in this case, while the temperature at which this step is performed can be selected in the range between 50° C. and 150° C., during the deposition process the wafer must be kept uniformly at the selected temperature.

In a semiconductor device production facility typically each Etcher, Asher, Stepper and plasma enhanced chemical vapour deposition (PECVD) chamber have their own TCU wherein a heat transfer fluid is recirculated.

Another process steps where heat transfer fluids are used in the manufacturing of semiconductor devices is vapour phase reflow (VPR) soldering. This is the most common method used to connect surface mount devices, multi chip modules and hybrid components to circuit boards. In this method the soldering material is applied in paste form and then the semiconductor device e.g. an unfinished circuit board is placed in a closed chamber with heat transfer fluid at its boiling point in equilibrium with its vapour phase. The fluid in vapour phase transfers heat to the soldering paste which then melts and stabilize the contacts. In this case the fluid is in direct contact with the circuit board so that it must be dielectric and non corrosive. For this application is also important that the boiling point of the heat transfer fluid is sufficient to melt the soldering paste.

Another system which is a key part of the production process of many semiconductor devices is thermal shock testing. In thermal shock testing a semiconductor device is tested at two very different temperature. Different standards exist, but in general the test consists in submitting the semiconductor device to high and low temperatures and then testing the physical and electronic properties of the device. Typically the semiconductor device to be tested is directly immersed alternatively in a hot bath (which can be at a temperature of from 60° C. to 250° C.) and a cold bath (which can be typically at a temperature of from −10° C. and −100° C.). The transfer time between the two bath must be minimized, generally below 10 seconds. Also in this test the fluid making up the baths go in direct contact with the device and therefore must be dielectric and non corrosive. In addition, to avoid contamination of the baths, it is highly preferable that the same fluid is used both in the cold and in the hot bath. Therefore heat transfer fluids which exist as liquid in a broad range of temperatures are preferred.

Many of the commonly used heat transfer fluids have limitations which make them not suitable for many applications in the semiconductor device manufacturing. For example deionized water and water/glycol mixtures are corrosive to the semiconductors and their temperature range is limited. Water/glycol mixtures are also too viscous in the lower temperature range of usability. Silicone oils and hydrocarbon oils are also sometimes used, however they are highly flammable and this severely limits their application field.

Heat transfer fluids which are currently used in the manufacturing of semiconductor devices are therefore typically liquids which are dielectric, non corrosive, and exist in the liquid state in a broad range of temperatures with relatively low viscosity which makes them easily pumpable.

Fluorinated liquid fluids are very effective heat transfer fluids. Commercial products exist such as Solvay's Galden and 3M's Fluorinert: these are liquid polymers which are dielectric, have a high heat capacity, a low viscosity and are non-toxic and chemically inert so they do not interact with the materials of the battery nor with its electronics. A drawback associated with these fluorinated fluids used so far is their high GWP value.

GWP (Global Warming Potential) is an attribute which can be determined for a given chemical compound which indicates how much heat a given greenhouse gas can entrap in the atmosphere (considering “1” as the reference value for CO₂) and is calculated over a specific interval of time, typically 100 years (GWP₁₀₀).

The determination of GWP100 is performed by combining experimental data concerning the atmospheric lifetime of the chemical compound and its radiative efficiency with specific computational tool which are standard in the art and are described e.g. in the extensive review published by Hodnebrog et. Al. in Review of Gephisics, 51/2013, p 300-378. Highly stable halogenated molecules such as CF₄ and chloro/fluoro alkanes have a very high GWP₁₀₀ (7350 for CF4, 4500 for CFC-11).

Over the years heat transfer fluids having elevated values of GWP (such as the chloro/fluoro alkanes used in air conditioning systems) have been phased out by the industry and replaced with compounds having a lower GWP₁₀₀ value and there is still a continuous interest in heat transfer fluids having GWP₁₀₀ values which are as low as possible.

Hydrofluoroethers, in particular segregated hydrofluoroethers, tend to have relatively low GWP₁₀₀ values while the rest of their properties can be compared to those of the CFCs used in the past, for this reason some hydrofluoroethers have been used industrially and gained popularity as heat transfer fluids and are marketed e.g. by 3M under the trade name “Novec®”.

Hydrofluoroethers are broadly described as heat transfer media due to their wide temperature range where they are liquid, and due to their low viscosity in a broad range of temperatures which makes them useful for applications as low temperature secondary refrigerants for use in secondary loop refrigeration systems where viscosity should not be too high at operating temperatures.

Fluorinated ethers are described for example by 3M in U.S. Pat. No. 5,713,211, by Dupont in US 2007/0187639 and by Solvay Solexis in WO 2007/099055 and WO2010034698.

However, while much lower than CFCs, the GWP₁₀₀ of segregated hydrofluoroethers is still in a range from 70 to 500 as shown in U.S. Pat. No. 5,713,211 (table 5):

| | GWP₁₀₀ |
|---|---|
| C₄F₉—O—CH₃ | 330 |
| C₄F₉—O—C₂H₅ | 70 |
| c-C₆F₁₁—O—CH₃ | 170 |

Other hydrofluoro-olefins have been commercialized as heat transfer fluids e.g. by Chemours (Opteon™) and Honeywell (Solstice™). These compounds have a very low GWP, around 1, but, differently from the formerly cited compounds, are much more flammable and therefore this limits their field of use.

Therefore there is still a need for effective heat transfer fluids for use in the manufacturing of semiconductor devices which have good dielectric properties, are liquid in a broad range of temperatures, are non flammable and have very low GWP (30 and below).

### SUMMARY OF INVENTION

The present invention relates to a method for manufacturing semiconductor devices, said method including a step wherein a semiconductor device exchanges heat with a heat transfer fluid which comprises one or more chemical compounds having the general formula:

Ph(OR_{f})ₓ (I)

wherein Ph is an aromatic ring linked to one or more ether groups —OR_{f} wherein each —R_{f} is a monovalent fluorinated alkyl group comprising at least one C—F bond, having a carbon chain which can be linear or can comprise branches and/or cycles, and, optionally, can comprise in chain heteroatoms selected from O, N or S, and wherein, when X>1, the —R_{f} groups on the same molecule can be equal or different from each other.

### DESCRIPTION OF EMBODIMENTS

The term “semiconductor device” in the present invention include any electronic device which exploits the properties of semiconductor materials. Semiconductor devices are manufactured both as single devices and as integrated circuits which consist of a number (which can go from two to billions) of devices manufactured and interconnected on a single semiconductor substrate or “wafer”. The term “semiconductor devices” includes both the basic building blocks, such as diodes and transistors, to the complex architectures built from these basic blocks which extend to analog, digital and mixed signal circuits, such as processors, memory chips, integrated circuits, circuit boards, photo and solar cells, sensors and the like. The term “semiconductor devices” also includes any intermediate or unfinished product of the semiconductor industry derived from a semiconductor material wafer.

As mentioned in the introduction, heat transfer fluids used during the manufacturing of semiconductor devices include fluorocompounds. In particular hydrofluorotethers have found application in this field due to their chemical inertness, dielectricity, wide range of T in which they are liquid and pumpable (typically having a viscosity between 1 and 50 cps at the temperatures of use), low flammability and relatively low GWP.

Commercially available hydrofluoroethers for use in this field are e.g. those from the Novec™ series of 3M which combine all these properties with a relatively low GWP₁₀₀ of from about 70 to 300.

Still, GWP is a critical property nowadays so that there is always a demand to develop new fluids which can be used in a BTMS which have even lower GWP than then currently commercialized hydrofluoroethers.

The present invention in fact relates to for manufacturing semiconductor devices, said method including a step wherein a semiconductor device exchanges heat with a heat transfer fluid, which comprises one or more chemical compounds having the general formula:

Ph(OR_{f})ₓ (I)

wherein Ph is an aromatic ring linked to one or more ether groups —OR_{f} wherein each —R_{f} is a monovalent fluorinated alkyl group comprising at least one C—F bond, and having a carbon chain which can be linear or can comprise branches and/or cycles, and, optionally, can comprise in chain heteroatoms selected from O, N or S, and wherein, when X>1, the —R_{f} groups on the same molecule can be equal to or different from each other.

The applicant has surprisingly found that the heat transfer fluid employed in the method of the invention is non-flammable, provides efficient heat transfer, can be used across a wide temperature range and has equal or improved dielectric properties with respect to other hydrofluoroethers commercialized as heat transfer fluids. Surprisingly heat transfer fluids used in the invention have an extremely low GWP₁₀₀, in general lower than 10 and for some materials even lower than 2, as it will be shown below in the experimental section. This is a particularly unexpected result and in fact previous reviews such as Hodnebrog et. al. cited above did not investigate or propose fluorinated aromatic ether compounds as low GWP compounds.

Therefore, using these selected chemical compounds in accordance to the general formula (I) heat transfer fluids can be formulated which have a GWP100 value of less than 30, preferably less than 10, even more preferably less than 5. The heat transfer fluids according to the invention also have low toxicity, exist in liquid state in a broad range from about −100° C. to about 200° C. showing good heat transfer properties and relatively low viscosity across the whole range. Also, the fluids of the invention have good electrical compatibility, i.e. they are non corrosive, have high dielectric strength, high volume resistivity and low solvency for polar material. The electrical properties of the fluids of the invention are such that they can be used in immersion cooling system for electronics in direct contact with the circuits as well as in indirect contact applications using loops and/or conductive plates.

Another important factor to consider is that heat transfer systems for semiconductor devices, while varying greatly in design and in the way the heat transfer fluid is distributed, in general require a heat transfer fluid which must exchange heat with the semiconductor device and which is then pumped and recirculated to a heat exchanger, external to the system which controls the temperature of the heat transfer fluid. Numerous parameters influence the capacity of a fluid to exchange heat. It has been found that using heat transfer fluids which have a Prandtl number between 3 and 100 at 40° C. and 1atm (101325 Pa) pressure allow to obtain optimum performance and energy efficiency of the system. Preferably heat transfer fluids to be employed in the method of the invention have a Prandtl number from 20-90, more preferably 30-80 and an even more preferably 40-70 at 40° C. and 1atm pressure.

The Prandtl number (Pr) is a dimensionless number defined as:

$$Pr = \frac{{c}_{p} μ}{k}$$

where:

cₚ=specific heat J/kg*K

μ=dynamic viscosity N*s/m²

k =Thermal conductivity W/mK

The Prandtl number indicates for a given fluid in given temperature (T) and pressure (P) conditions what is the predominant phenomenon among heat conduction and heat convection. A Prandtl number lower than 1 indicates that conduction is more significant than convection while a Prandtl number higher than 1 indicates that convection is more significant than conduction. The Prandtl number if commonly found in the property tables of heat transfer fluids provided by the fluid manufacturers.

Preferably, compounds according to the general formula (I) for the present invention have a value of x selected from 1, 2, 3 or 4, more preferably x is selected from 2 and 3, even more preferably x=2. Each R_{f} has preferably a C₁-C₁₁₀, more preferably a C₂-C₆ carbon chain which can be linear or comprise branches and/or cycles. The carbon chain may optionally include in chain heteroatoms selected from O, N or S, in case in chain heteroatoms are present it is preferred that the heteroatom is 0.

As mentioned above each R_{f} group must comprise at least one C—F bond. Preferably each R_{f} group also comprises at least one C—H bond. More preferably each R_{f} is a fluorinated alkyl group with one single C—H bond, even more preferably wherein said single C—H bond is on the carbon atom in position 2 of the carbon chain.

Of the six C atoms of the Ph ring, x are bonded to —OR_{f} groups and (6-x) can be bonded to any type of substituents, preferably they are bonded to H atoms or to F atoms, more preferably H atoms.

Compounds according to the formula (I) for use in the method of the invention can be easily prepared by reacting mono or polyhydric phenols with fluorinated olefins, preferably fully fluorinated olefins. The Ph—OH group adds to the double C═C bond and the H atom adds on the C atom in position 2. The resulting compound is a thus hydrofluoroether. This hydrofluoroether can be further fluorinated to a perfluoroether, but preferably is used as a hydrofluoroether, as already mentioned above.

Preferred mono and polyhydric phenols for use herein are phenol, hydroquinone, resorcinol and catechol. Preferred fluorinated olefins for use herein are tetrafluoroethylene, hexafluoropropylene and perfluorovinylethers such as perfluoromethylvinylether, perfluoroethylvinylether and perfluoropropylvinylether.

Most preferred compounds among those encompassed by the general formula mentioned above are: 1,4-bis(1,1,2,2-tetrafluoroethoxy)benzene of formula:

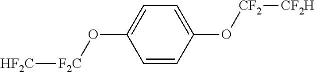

1,4-bis(2-trifluoromethyl-1,1,2-trifluoroethoxy)benzene of formula :

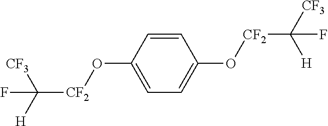

and their corresponding ortho and meta isomers

1,3-bis(1,1,2,2-tetrafluoroethoxy)benzene

1,3-bis(2-trifluoromethyl-1,1,2-trifluoroethoxy)benzene

1,2-bis(1,1,2,2-tetrafluoroethoxy)benzene

1,2-bis(2-trifluoromethyl-1,1,2-trifluoroethoxy)benzene,

and the corresponding derivatives of perfluoromethylvinylether with catechol, resorcinol and hydroquinone:

1,2-bis(2-trifluoromethoxy-1,1,2-trifluoroethoxy)benzene

1,3-bis(2-trifluoromethoxy-1,1,2-trifluoroethoxy)benzene

1,4-bis(2-trifluoromethoxy-1,1,2-trifluoroethoxy)benzene

The heat transfer fluids for use in the method of invention preferably comprise more than 5% of one or more compounds according to formula (I) above, more preferably more than 50%, even more preferably more than 90%. In one embodiment the heat transfer fluid is entirely made of one or more compounds according to the general formula above.

In some embodiments the heat transfer fluid of the invention comprises a blend of chemical compounds according to formula (I). A blend may be beneficial in providing a fluid which is liquid in a larger temperature range. A preferred blend is a blend comprising at least two different isomers having the same substituents in different positions of the aromatic ring.

In all embodiments it is preferred that the heat exchange fluid is essentially free of CFCs and fluoroalkanes such as 1,1,1,2-tetrafluoroethane, 1,1-difluoromethane, 1,1,1,2,2,pentafluoroethane. These materials have a high GWP₁₀₀ and even in minor amount contribute to the GWP₁₀₀ of the heat exchange fluid more than its main components according to formula (I).

For “essentially free” it is intended that the heat exchange fluid in the present invention comprises less than 5%, preferably less than 1%, more preferably less than 0.1% of a given component (all percentages are expressed as weight percent of the total of the heat exchange fluid).

The heat transfer fluids of the invention can be used in all the steps of the manufacturing of semiconductor devices which require the semiconductor device to exchange heat with a heat transfer fluid. In particular when using semiconductor processing equipment such as an Etcher, an Asher, a Stepper and a plasma enhanced chemical vapour deposition (PECVD) chamber, each of these equipment require precise temperature control and/or heat dissipation and therefore they are equipped with temperature control units (TCUs) which can include the selected heat transfer fluid of the method of the invention.

Additionally in thermal shock testing, which is an integral part of semiconductor device manufacturing because only those devices which pass the test are processed further, the semiconductor device is cooled and heated using at least two baths, a cold one typically at a temperature of from −10 and −100° C., and a hot one typically at a temperature of from 60° C. and 250° C. The selected heat transfer fluid of the method of the invention can be advantageously used in said bath and, since the same fluid can be used in both bath thanks to the large temperature range in which the fluid is in liquid state, there is no risk of cross contamination of the baths.

The method of the invention can also find application in vapor phase soldering, in fact the selected heat transfer fluid of the method of the invention can be formulated so to have a boiling point in line with that of the soldering paste, so that a semiconductor device comprising soldering paste which still has to be “cured” can be introduced into a closed chamber which contains the selected heat transfer fluid of the method of the invention at its boiling point in equilibrium with its heated vapors. The heated vapors will transfer heat to the semiconductor device thereby melting the soldering paste and therefore fixing the contacts as needed.

An additional advantage is that a single heat transfer fluid can be used in multiple applications potentially allowing the use of a single heat transfer fluid across an entire semiconductor devices manufacturing facility.

In an aspect the present invention relates to a method for exchanging heat with a semiconductor device, said method comprising using one or more semiconductor processing equipment selected from an Etcher, an Asher, a Stepper and a plasma enhanced chemical vapour deposition (PECVD) chamber, said semiconductor processing equipment including at least one temperature control unit (TCU) exchanging heat with said semiconductor device, said TCU comprising a heat transfer fluid, said heat transfer fluid comprising one or more chemical compounds having the general formula:

Ph(OR_{f})ₓ (I)

wherein Ph is an aromatic ring linked to one or more ether groups —OR_{f} where each −R_{f}:
is a monovalent fluorinated alkyl group comprising at least one C—F bond,
has a carbon chain, preferably a C₁-C₁₀ carbon chain, which can be linear or can comprise branches and/or cycles, and, optionally, can comprise in chain heteroatoms selected from O, N or S, and wherein, when X>1, the —R_{f} groups on the same molecule can be equal to or different from each other.

In a further aspect the present invention relates to a method for thermal shock testing of semiconductor devices, said method comprising, in any order:

i. cooling said semiconductor device to a temperature comprised from −10° C. and −100° C., preferably from −40° C. and −80° C., using a first bath being made of a heat transfer fluid and

ii. heating said semiconductor to a temperature comprised from 60° C. and 250°, using a second bath being made of said heat transfer fluid.
wherein said heat transfer fluid comprises one or more chemical compounds having the general formula:

Ph(OR_{f})ₓ (I)

wherein Ph is an aromatic ring linked to one or more ether groups —OR_{f} where each —R_{f}:
is a monovalent fluorinated alkyl group comprising at least one C—F bond,
has a carbon chain, preferably a C₁-C₁₀ carbon chain, which can be linear or can comprise branches and/or cycles, and, optionally, can comprise in chain heteroatoms selected from O, N or S, and wherein, when X>1, the —R_{f} groups on the same molecule can be equal to or different from each other.

In another aspect the present invention relates to a method of vapour phase soldering for semiconductor devices wherein a heat transfer fluid is used as heat source said method including
i. providing a semiconductor device comprising soldering paste,
ii. providing a closed chamber comprising said heat transfer fluid at its boiling point so that heated vapors of said heat transfer fluid are generated within said closed chamber
iii. introducing said semiconductor device in said closed chamber, in contact with said vapors of said heat transfer fluid thereby melting said soldering paste by contact with said heated vapors

wherein said heat transfer fluid comprises one or more chemical compounds having the general formula:

Ph(OR_{f})ₓ (I)

wherein Ph is an aromatic ring linked to one or more ether groups —OR_{f} where each —R_{f}:
is a monovalent fluorinated alkyl group comprising at least one C—F bond,
has a carbon chain, preferably a C₁-C₁₀ carbon chain, which can be linear or can comprise branches and/or cycles, and, optionally, can comprise in chain heteroatoms selected from O, N or S, and wherein, when X>1, the —R_{f} groups on the same molecule can be equal to or different from each other.

Should the disclosure of any patents, patent applications, and publications which are incorporated herein by reference conflict with the description of the present application to the extent that it may render a term unclear, the present description shall take precedence.

The invention will be now described in more detail with reference to the following examples whose purpose is merely illustrative and not limitative of the scope of the invention.

### Raw Materials Used

Hydroquinone, KOH, acetonitrile were all sourced from Sigma Aldrich Tetrafluoroethylene was sourced from Solvay. Novec™ 7000, 7100 and 7200 are commercially available hydrofluoroethers from 3M

### Standards

Measurement of electrical properties were performed according to the following standards:

Volume resistivity—ASTM D5682-08[2012]

Dielectric strength—ASTM D877/D877M-13

Dielectric constant—ASTM D924-15

### EXAMPLES

Synthesis of 1,4-Bis(1,1,2,2-tetrafluoroethoxy)benzene (HFE 1,4): In a 600 mL steel autoclave were loaded 60.0 g of hydroquinone, with 16 g of KOH and 360 mL of acetonitrile. The autoclave was purged four times with nitrogen and drawn to moderate vacuum (0.2bar).

The mixture was stirred vigorously for 30 minutes at 70° C., then tetrafluoroethylene was introduced gradually up to 10 bar in 6 hours. The reactor was left stirring for a total of 20 h, then it was cooled and tetrafluoroethylene pressure was released. Its content was then purged four times with nitrogen. Consumption of tetrafluoroethylene was 110 g.

468 g of mixture were unloaded from reactor. This mixture was diluted in a separator funnel with 1.5 L water and neutralized with hydrochloric acid. The organic layer at the bottom was washed two times with 0.5 L of water and then finally separated from the top water layer, dried over MgSO₄, filtered and distilled at 94° C. at a reduced pressure of 15 mbar.

150 g of pure 1,4-bis(1,1,2,2-tetrafluoroethoxy)benzene were obtained.

The GWP₁₀₀ for HFE1,4 has been determined at the University of Oslo according to established procedures, by measuring the integrated absorption cross section of infrared spectra over the region 3500-500 cm⁻¹, the kinetic of reaction with OH radicals, and calculating the consequent atmospheric lifetime and radiative forcing efficiency. As a result of these measurements a GWP₁₀₀ of 1.8 has been obtained.

HFE1,4 data relevant to GWP₁₀₀:

Integrated absorption cross section at 3500-500cm⁻¹:

53.6 cm² molecule⁻¹ cm⁻¹

Radiative forcing efficiency (calc)=0.165 W m⁻²

OH radicals kinetic k_{HFE1,4+OH}=2×10⁻¹³ cm³ molecule⁻¹ s⁻¹ at 298K

Atmospheric lifetime of HFE1,4=2 months

GWP₁₀₀=1.8

Electric and thermal properties of HFE1,4 in comparison with other commercially available hydrofluoroethers:

| | | Volume | Dielectric | |
|---|---|---|---|---|
| | | resistivity | strength | Dielectric |
| | GWP₁₀₀ | (ohm cm−1) | (kV) | constant |
| NOVEC 7200 | 70 | 1.00E+08 | 30 | 7.3 |
| NOVEC 7000 | 530 | 1.00E+08 | 40 | 7.4 |
| HFE1,4 | 1.8 | 2.00E+9 | 45 | 6.2 |

Other physical properties of compounds according to the invention:

1,4-Bis(1,1,2,2-tetrafluoroethoxy)benzene (HFE 1,4)

1,3-Bis(1,1,2,2-tetrafluoroethoxy)benzene (HFE 1,3)

1,2-Bis(1,1,2,2-tetrafluoroethoxy)benzene (HFE 1,2)

| | HFE1,4 | HFE1,3 | HFE1,2 |
|---|---|---|---|
| Dielectric constant @1 kHz | 6.2 | 7.84 | |
| Dielectric strength kV | 45 | | |
| Volume resistivity Ohm*cm | 2E+09 | 1E+10 | |
| heat capacity cal/g° C., | 0.34 | | |
| viscosity (25° C.) cSt, | 3.56 | 2.75 | 2.86 |
| density (25° C.) g/cm3, | 1.5 | 1.5 | 1.5 |
| heat of vaporization kcal/kg | 34 | | |
| surface tension mN/m | 28 | | |
| pour point ° C. | −10 | −93 | −87 |
| Boiling point ° C. | 202 | 192 | 206 |

The results show how the compounds of the invention have overall equal or improved properties when compared with existing commercial fluids used for similar purposes and have lower GWP. Heat transfer fluids comprising these compounds can be used in the method of the invention, particularly in the applications described i.e. in TCUs for production equipment such Etchers, Ashers, a Steppers and plasma enhanced chemical vapour deposition (PECVD) chambers, and/or in baths for thermal shock testing of semiconductor devices and/or for vapor phase soldering of semiconductor devices.

1-12. (canceled)

13. A method for manufacturing semiconductor devices, said method including a step wherein a semiconductor device exchanges heat with a heat transfer fluid, said heat transfer fluid comprising one or more chemical compounds having the general formula:
a. Ph(OR_{f})ₓ (I)
wherein Ph is an aromatic ring linked to one or more ether groups —OR_{f} where each —R_{f}:
is a monovalent fluorinated alkyl group comprising at least one C—F bond,
has a carbon chain which is linear or comprise branches and/or cycles, and, optionally, comprises in chain heteroatoms selected from O, N or S,
and wherein, when X>1, the —R_{f} groups on the same molecule can be equal to or different from each other.

14. A method according to claim 13 said method comprising using one or more of a semiconductor processing equipment selected from an Etcher, an Asher, a Stepper and a plasma enhanced chemical vapour deposition (PECVD) chamber, said semiconductor processing equipment including at least one temperature control unit (TCU) exchanging heat with said semiconductor device, wherein said TCU comprises said heat transfer fluid.

15. A method according to claim 13 which is a method for thermal shock testing of semiconductor devices, said method comprising, in any order:
i. cooling said semiconductor device to a temperature comprised from −10° C. and −100° C. using a first bath being made of said heat transfer fluid and
ii. heating said semiconductor to a temperature from 60° C. and 250° , using a second bath being made of said heat transfer fluid.

16. A method according to claim 13 which is a method for vapor phase soldering of semiconductor devices, said method including
i. providing a semiconductor device comprising soldering paste,
ii. providing a closed chamber comprising said heat transfer fluid at its boiling point so that heated vapors of said heat transfer fluid are generated within said closed chamber
iii. introducing said semiconductor device in said closed chamber, in contact with said vapors of said heat transfer fluid thereby melting said soldering paste by contact with said heated vapors.

17. A method according to claim 13 wherein, in said chemical compound having general formula (I), x is selected from 1, 2, 3 and 4.

18. A method according to claim 13 wherein, in said chemical compound having general formula (I), multiple R_{f} groups on the same molecule are equal to each other.

19. A method according to claim 13 wherein, in said chemical compound having general formula (I), each R_{f} group comprises at least one C—H bond.

20. A method according to claim 13 wherein, in said chemical compound having general formula (I), each R_{f} group has exactly one C—H bond.

21. A method according to claim 20 wherein, in said chemical compound having general formula (I), each R_{f} group has exactly one C—H bond on the carbon atom in position 2.

22. A method according to claim 13 wherein said one or more chemical compounds of general formula (I) make up at least 5% by weight of said heat transfer fluid.

23. A method according to claim 13 wherein said compound is selected from
1,4-bis(1,1,2,2-tetrafluoroethoxy)benzene,
1,4-bis(2-trifluoromethyl-1,1,2-trifluoroethoxy)benzene,
1,3-bis(1,1,2,2-tetrafluoroethoxy)benzene,
1,3-bis(2-trifluoromethyl-1,1,2-trifluoroethoxy)benzene,
1,2-bis(1,1,2,2-tetrafluoroethoxy)benzene,
1,2-bis(2-trifluoromethyl-1,1,2-trifluoroethoxy)benzene,
1,2-bis(2-trifluoromethoxy-1,1,2-trifluoroethoxy)benzene,
1,3-bis(2-trifluoromethoxy-1,1,2-trifluoroethoxy)benzene,
1,4-bis(2-trifluoromethoxy-1,1,2-trifluoroethoxy)benzene
and mixtures thereof.

24. A method according to claim 13 wherein said heat transfer fluid has a GWP100 of less than 30.
